(19) United States
(12) Patent Application Publication
(10) Pub. No.: US 2018/0145188 A1
(43) Pub. Date: May 24, 2018

(54) STACKED SEMICONDUCTOR STRUCTURE

(71) Applicant: AZUR SPACE Solar Power GmbH, Heilbronn (DE)

(72) Inventors: Daniel FUHRMANN, Heilbronn (DE); Wolfgang GUTER, Stuttgart (DE); Victor KHORENKO, Neuenstadt a.K. (DE)

(73) Assignee: AZUR SPACE Solar Power GmbH, Heilbronn (DE)

(21) Appl. No.: 15/817,965

(22) Filed: Nov. 20, 2017

(30) Foreign Application Priority Data
Nov. 18, 2016 (DE) 10 2016 013 749.5

(51) Int. Cl. H01L 29/88; H01L 21/308; H01L 25/075; H01L 33/26; H01L 33/00

(52) U.S. Cl. CPC H01L 29/88; H01L 21/308; H01L 25/0756; H01L 33/26; H01L 21/24; H01L 33/0008; H01L 33/0062; H01L 2924/12036; H01L 33/0025

(57) ABSTRACT

A stacked semiconductor structure having a number of semiconductor diodes connected to one another in series, wherein each semiconductor diode has a p-n junction, and a tunnel diode is formed between sequential pairs of semiconductor diodes. The semiconductor diodes and the tunnel diodes jointly form a stack with a top and a bottom, and the number of semiconductor diodes is greater than or equal to two. When the stack is illuminated with light, at 300 K the stack has a source voltage of greater than 2 volts, and from the top of the stack to the bottom, a total thickness of the p and n absorption layers of a semiconductor diode increases from the topmost to the bottommost diode. The semiconductor diodes have substantially the same band gap, and the stack is formed on a substrate.

This nonprovisional application claims priority under 35 U.S.C. § 119(a) to German Patent Application No. 10 2016 013 749.5, which was filed in Germany on Nov. 18, 2016, and which is herein incorporated by reference.

### BACKGROUND OF THE INVENTION

### Field of the Invention

The invention relates to a stacked semiconductor structure.

### Description of the Background Art

Stacked semiconductor structures made of III-V materials are known from U.S. Pat. No. 4,127,862.

### SUMMARY OF THE INVENTION

It is therefore an object of the invention is to provide a device that advances the state of the art.

According to an exemplary embodiment of the invention, a stacked semiconductor structure is provided, having a number N of semiconductor diodes connected to one another in series.

Each semiconductor diode has a p-n junction and a p-doped absorption layer and an n absorption layer, wherein the n absorption layer is passivated by an n-doped passivation layer with a larger band gap than the band gap of the n absorption layer. Each p absorption layer of the semiconductor diode is passivated by a p-doped passivation layer with a larger band gap than the band gap of the p absorption layer.

A tunnel diode is formed between sequential pairs of semiconductor diodes, wherein the tunnel diode has multiple semiconductor layers with a higher band gap than the band gap of the p/n absorption layers, and the semiconductor layers with the higher band gap are each made of a material with modified stoichiometry and/or a different elemental composition than the p/n absorption layers of the semiconductor diode.

The semiconductor diode and the tunnel diodes may be monolithically integrated together, and jointly form a stack with a top and a bottom.

The number N of semiconductor diodes is greater than or equal to two. When the stack is illuminated with light, at 300 K the stack has a source voltage of greater than 2 volts.

The light is incident on a surface of the stack at the top. The size of the illuminated surface on the stack top corresponds essentially to the size of the area of the stack at its top.

In the direction of incident light, starting from the top of the first stack to the bottom of the stack, the total thickness of the p and n absorption layers of the semiconductor diode increases from the topmost diode to the bottommost diode.

The semiconductor diodes can have the same band gap or a difference of less than 0.1 eV in the band gap. The total thickness of the stack should be less than 20 μm. The stack can be arranged on a substrate.

Formed in the vicinity of the bottom of the stack is a continuous, shoulder-like primary step with a platform surface. The edge of the primary step is a minimum of 5 μm and a maximum of 500 μm distant from the immediately adjacent lateral face of the stack.

The lateral faces of the semiconductor layers are formed by means of an etching process, and have an average roughness value Ra between 0.002 μm and 0.2 μm.

The stack that is arranged with its bottom on a substrate, and the substrate, each include or are made of a semiconductor material.

It should be noted that the expression “corresponds essentially” in the context of the comparison of the illumination area at the stack top with the size of the area of the first stack at the top can be understood to mean that a difference in the area is, for example, less than 20%, or preferably less than 10%, or preferably less than 5%, or most preferably the two areas are equal. In other words, the non-illuminated area at the stack top is less than 20%, or preferably less than 10%, or preferably less than 5% of the size of the area of the first stack at the top.

It should also be noted that the term “light” for irradiating the stack top can be understood to mean a light that has a spectrum of wavelengths in the absorption range of the absorption layers. It is a matter of course that a monochromatic light, for example through illumination with a light emitting diode or a laser diode as the illumination source, that has a certain wavelength, i.e., absorbing wavelength, which is to say a wavelength in the absorption range of the absorption layers, is also suitable.

It is a matter of course that preferably the entire top of the first stack, which is to say the entire or nearly the entire surface, is irradiated with light of a certain wavelength. It should be noted that thorough investigations have demonstrated, surprisingly, that in contrast to the prior art, source voltages above 2V advantageously result with the present monolithic stack approach.

An advantage of the device according to the invention is that the semiconductor structures can be separated reliably and economically as a result of the etching and the formation of a continuous step. A sawing process for dividing the substrate is not carried out until after the etching process. Under no circumstances are the lateral faces of the stack reshaped by the sawing process. In other words, after formation of a continuous trench by a masking step and formation of the stacks, the stacks are separated by means of the saw.

An adverse effect on the electrical properties due to the sawing apart of the individual structures is reduced or avoided entirely. The etching can be performed by a wet chemical process as well as by an RIE process, which is to say a dry etching process, or by means of a combination.

It is a matter of course that the etching processes have the highest possible anisotropy, i.e., the etching rate perpendicular to the surface of the stack is significantly higher than the etching rate in the direction of the surface. “Significantly higher” can be understood in the present case to mean at least a factor of 2, preferably at least a factor of 10, and most preferably at least a factor of 100. Preferably, the etching stops in the substrate or on the substrate.

Another advantage is that the stacked arrangement of the diodes results in a great saving in area as compared to the previous lateral arrangement with silicon diodes. In particular, only the considerably smaller receiving area of the stack should be illuminated.

In an embodiment, an intermediate layer can be arranged between the substrate and the bottom of the stack in order to achieve a monolithic bond between the bottom of the stack and the top of the substrate. The intermediate layer includes a nucleation layer and/or a buffer layer.

In an embodiment, the platform surface of the primary step can be formed on the top of the substrate or in the substrate or on the top of the intermediate layer or in the intermediate layer.

In an embodiment, the normal of the lateral face of the stack can be in an angular range between 75° and 115° or in an angular range between 95° and 105° in comparison to the normal of the platform surface. In other words, the lateral face of the stack is either exactly perpendicular, which is to say at 90° to, the platform surface, or is inclined in an angular range of ±15° or ±5°.

In an embodiment, the platform surface can be flat in design and/or the platform surface can have a difference in depth around the perimeter of less than a factor of 4, or has no difference in depth. In other words, if the platform surface of the primary step has no difference in depth, the outer edge is a uniform distance from the lateral face of the stack all around the perimeter.

In an embodiment, secondary steps with a step depth of less than 5 μm are formed on the lateral faces of the stack between two immediately successive semiconductor layers. For example, the depth of the secondary step is less than 1 μm or less than 0.2 μm. Of course, the smaller the depth of the secondary steps, the flatter the lateral faces are, and also the more easily and reliably the faces can be passivated. For example, the minimum depth of the secondary step is more than 0.01 μm.

In an embodiment, the partial source voltages of the individual partial voltage sources can differ from one another by less than 10%. As a result, the semiconductor structure can be used as a scalable voltage source. It is a matter of course that the term “scalability” refers to the size of the source voltage of the entire stack.

In an embodiment, the semiconductor diodes each can have the same semiconductor material, wherein the semiconductor material of the diodes has the same crystalline composition and the stoichiometry preferably is nearly the same or preferably is exactly the same.

In an embodiment, the semiconductor diodes can be made of the same material as the substrate. One advantage is that the coefficients of expansion, in particular, of the two parts are then the same. It is advantageous when the semiconductor diodes are made fundamentally of one III-V material. In particular, it is preferred to use GaAs.

In an embodiment, the semiconductor material and/or the substrate can be formed of III-V materials. In particular, it is also preferred that the substrate includes germanium or gallium arsenide and/or that the semiconductor layers on the substrate have arsenic and/or phosphorus.

In other words, the semiconductor layers include As-containing layers and P-containing layers, which is to say layers of GaAs or AlGaAs or InGaAs as examples of arsenide layers and InGaP as an example of phosphide layers.

In addition, the first stack can have a base area smaller than 4 mm² or smaller than 2 mm² or smaller than 1 mm². It is advantageous to design the base area to be quadrilateral or circular, for example, round. Preferably the base area of the stack is designed as a square or as a circle or as an ellipse.

In an embodiment, a first terminal contact is formed on the top of the first stack as a continuous metal contact in the vicinity of the edge or as a single contact area on the edge.

It is preferred to form a second terminal contact on the bottom of the first stack and, in particular, that the second terminal contact is planar in design or preferably is formed on the entire bottom of the substrate.

In addition, it is preferred for a semiconductor mirror to be formed below the bottommost semiconductor diode of the stack.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is an electrotechnical equivalent circuit diagram of a stack ST1 of a semiconductor structure HL according to the invention,

FIG. 2 is a cross-sectional view of a semiconductor structure HL,

FIG. 3 is a perspective view of a semiconductor structure HL, and

FIGS. 4a-e show a detailed cross-sectional view of the etching depth for the formation of the continuous step with respect to the etching depth.

### DETAILED DESCRIPTION

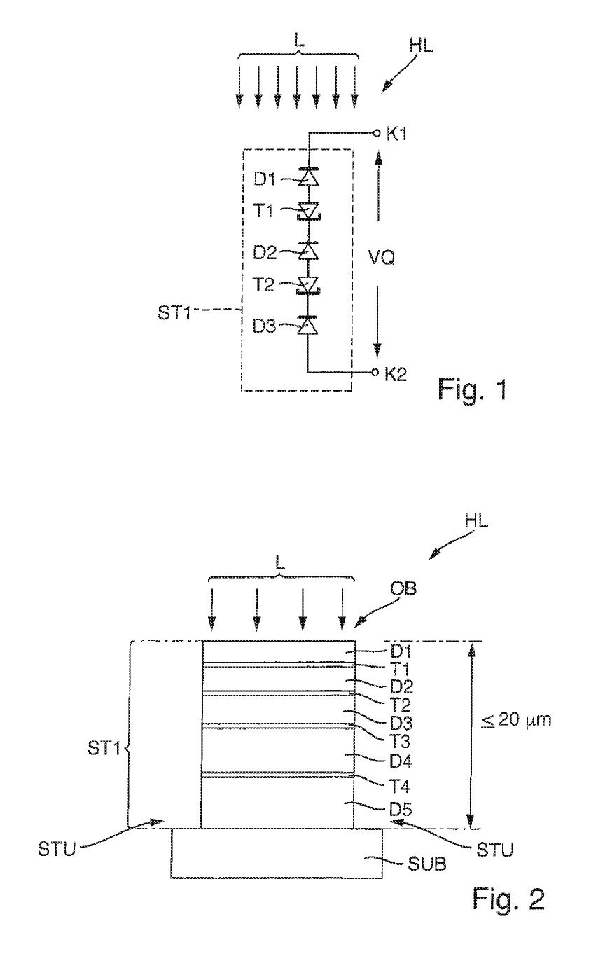

The illustration in FIG. 1 shows an electrotechnical equivalent circuit diagram of a stack ST1 of a semiconductor structure HL according to the invention.

The semiconductor structure HL includes a stack ST1 with a top and a bottom with a number N equal to three diodes. The stack ST1 has a series circuit formed of a first diode D1 and a first tunnel diode T1 and a second diode D2 and a second tunnel diode T2 and a third diode D3. Formed on the top of the stack ST1 is a first terminal contact K1 and on the bottom of the stack ST1 is a second terminal contact K2. The source voltage VQ of the stack ST1 in the present case is composed of the partial voltages of the individual diodes D1 to D3 combined. For this purpose, the first stack ST1 is exposed to a photon flux, which is to say the light L.

The stack ST1 of the diodes D1 to D3 and the tunnel diodes T1 and T2 is implemented as a monolithic block, preferably made of the same semiconductor material.

In the illustration in FIG. 2, a cross-sectional view of a semiconductor structure HL is shown. Only the differences from the illustration in FIG. 1 are explained below. The semiconductor structure HL includes the stack ST1 and a semiconductor substrate formed below the stack ST1.

The first stack ST1 comprises a total of five diodes D1 to D5 connected in series. The light L is incident on the surface OB of the first diode D1, which in the present case also forms the top of the stack ST1. The surface OB is completely or almost completely illuminated. One tunnel diode T1-T4 is formed in each case between the diodes D1-D5.

The thickness of the absorption region increases with increasing distance of the individual diodes D1 to D5 from the surface OB, so that the bottommost diode D5 has the thickest absorption region. Taken as a whole, the total thickness of the first stack ST1 is less than or equal to 20 μm.

The substrate SUB is formed beneath the bottommost diode D5, which in the present case also forms the bottom of the stack ST1. The lateral extent of the substrate SUB is greater than the lateral extent of the stack on the bottom thereof so that a continuous primary step STU is formed.

The primary step STU is monolithically joined to the stack. In order to form the stack, an etching down to the substrate is carried out after the full-area, preferably epitaxial, production of all layers of the semiconductor structure HL.

For this purpose, a resist mask is created by means of a masking process and then wet chemical etching is performed to create the trenches. The etching stops in the substrate or on the substrate or in an intermediate layer formed between the substrate and the stack bottom.

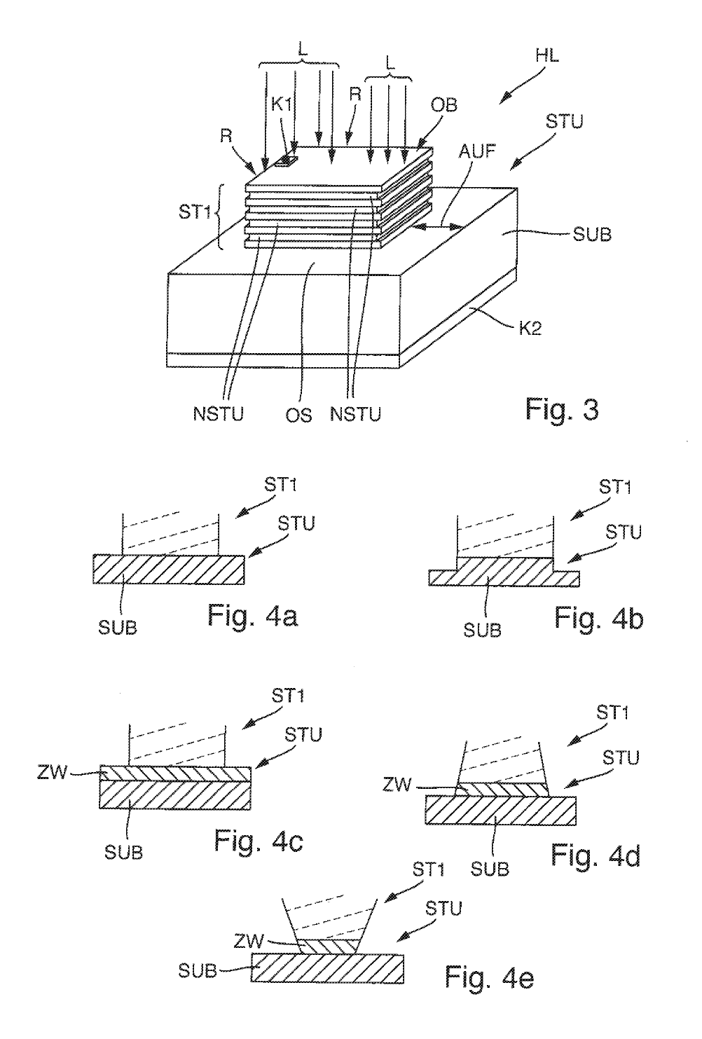

In the illustration in FIG. 3, a perspective view of a semiconductor structure HL is shown. Only the differences from the embodiments shown in the preceding figures are explained below.

A first metal terminal contact K1 is formed on the surface of the stack ST1 at the edge R. The substrate SUB has, on the top, a platform surface AUF of the primary step STU.

The stack ST1 has a square base area with four vertical lateral faces. By the means that the individual semiconductor layers of the stack ST1 have somewhat different lateral etching rates, a plurality of secondary steps NSTU with a shallow step depth are formed along the vertical direction of the lateral faces.

The top of the substrate SUB is integrally joined to the bottommost diode, which is to say the fifth diode D5.

In an embodiment that is shown later, an intermediate layer having a thin nucleation layer and/or a buffer layer is formed on the substrate SUB, which is to say the bottom of the stack ST1 is integrally joined to the intermediate layer.

The top OS of the substrate SUB has a larger surface than the area at the bottom of the stack ST1. In this way, the continuous primary step STU is formed. The edge of the primary step STU is more than 5 μm and less than 500 μm distant from the immediately adjacent lateral face of the first stack ST1 of the primary step, shown as the depth of the platform surface AUF.

A second, full-area metal terminal contact K2 is formed on the bottom of the substrate SUB.

The illustrations in FIG. 4a-e show detailed cross-sectional views of various embodiments for the formation of the continuous primary step with respect to the etching depth. The lateral faces of the stack ST1 are shown only partially with regard to the height.

In the illustration in FIG. 4a, the primary step STU is formed at the boundary between the substrate SUB and the bottom of the stack ST1. No intermediate layer ZW is present between the substrate SUB and the first stack ST1, which is to say the substrate SUB is integrally joined to the bottom of the stack ST1. In other words, the etching process was very selective and anisotropic, and stopped at the material of the substrate SUB.

In the illustration in FIG. 4b, the primary step STU is formed in the substrate SUB. The etching process was not selective or was only slightly selective between the layers of the stack ST1 and the material of the substrate SUB.

In an embodiment that is not shown, the primary step STU is formed in the substrate SUB, and the substrate SUB is integrally joined to the bottom of the intermediate layer ZW, and the bottom of the stack ST1 is integrally joined to the top of the intermediate layer ZW.

In the illustration in FIG. 4c, the primary step STU is formed at the boundary between the intermediate layer ZW and the bottom of the stack ST1. “The intermediate layer ZW is formed between the substrate SUB and the stack ST1, which is to say the substrate SUB is integrally joined to the bottom of the intermediate layer ZW, and the bottom of the stack ST1 is integrally joined to the top of the intermediate layer ZW. In other words, the etching process was very selective and anisotropic, and stopped at the material of the intermediate layer ZW.

In the illustration in FIG. 4d, the primary step STU is formed at the boundary between the substrate SUB and the bottom of the intermediate layer ZW. The lateral faces of the stack are inclined towards one another, and form an angle greater than 90° with the surface of the substrate.

The intermediate layer ZW is formed between the substrate SUB and the stack ST1, which is to say the substrate SUB is integrally joined to the bottom of the intermediate layer ZW, and the bottom of the stack ST1 is integrally joined to the top of the intermediate layer ZW. The intermediate layer is completely removed or nearly completely removed above the platform surface AUF of the primary step. In other words, the etching process was very selective and anisotropic, and stopped at the substrate SUB.

In the illustration in FIG. 4e, the primary step STU is formed at the boundary between the substrate SUB and the bottom of the intermediate layer ZW. The lateral faces of the stack are inclined away from one another, and form an angle less than 90° with the surface of the substrate.

The intermediate layer ZW is formed between the substrate SUB and the stack ST1, which is to say the substrate SUB is integrally joined to the bottom of the intermediate layer ZW, and the bottom of the stack ST1 is integrally joined to the top of the intermediate layer ZW. The intermediate layer is completely removed or nearly completely removed above the platform surface AUF of the primary step. In other words, the etching process was very selective and anisotropic, and stopped at the substrate SUB.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A stacked semiconductor structure comprising:
a number of semiconductor diodes connected to one another in series, each semiconductor diode of the number of semiconductor diodes has a p-n junction, a p-doped absorption layer, and an n absorption layer, the n absorption layer being passivated by an n-doped passivation layer with a larger band gap than a band gap of the n absorption layer, and the p absorption layer of the semiconductor diode being passivated by a p-doped passivation layer with a larger band gap than a band gap of the p absorption layer; and
a tunnel diode formed between sequential pairs of semiconductor diodes, the tunnel diode having multiple semiconductor layers with a higher band gap than a band gap of the p/n absorption layers, the semiconductor layers with the higher band gap are each made of a material with a modified stoichiometry and/or a different elemental composition than the p/n absorption layers of the semiconductor diode,
wherein the semiconductor diode and the tunnel diodes are monolithically integrated together, and jointly form a stack with a top and a bottom, and the number of semiconductor diodes is greater than or equal to two,
wherein, when the stack is illuminated with light at 300 K, the stack has a source voltage of greater than 2 volts, the light being incident on a top surface of the stack,
wherein, a size of the illuminated surface on the top surface corresponds essentially to a size of an area of the stack at its top,
wherein, in a direction of incident light, from the top surface towards a bottom of the stack, a total thickness of the p and n absorption layers of a semiconductor diode increases from the topmost diode towards the bottommost diode,
wherein the semiconductor diodes have a same band gap or a difference of less than 0.1 eV in the band gap,
wherein the stack has a total thickness of less than 20 μm, and is formed on a substrate,
wherein, formed in a vicinity of the bottom of the stack, is a continuous, shoulder-like primary step with a platform surface, an edge of the primary step being a minimum of 5 μm and a maximum of 500 μm distant from an immediately adjacent lateral face of the stack,
wherein the lateral faces of the semiconductor layers that form the stack are produced via an etching process and have an average roughness value Ra between 0.002 μm and 0.2 μm, and
wherein the stack is arranged with its bottom on a substrate, and the substrate includes a semiconductor material.

2. The stacked semiconductor structure according to claim 1, wherein an intermediate layer is arranged between the substrate and the bottom of the stack to achieve a monolithic bond between the bottom of the stack and the top of the substrate, and wherein the intermediate layer includes a nucleation layer and/or a buffer layer.

3. The stacked semiconductor structure according to claim 2, wherein the platform surface of a primary step is formed on the top of the substrate or in the substrate or on the top of the intermediate layer or in the intermediate layer.

4. The stacked semiconductor structure according to claim 1, wherein a normal of the lateral face of the stack is in an angular range between 75° and 115° or in an angular range between 95° and 105° in comparison to a normal of the platform surface.

5. The stacked semiconductor structure according to claim 1, wherein the platform surface of the primary step is flat in design or the platform surface has a difference in depth around a perimeter of less than a factor of 4, or has no difference in depth.

6. The stacked semiconductor structure according to claim 1, wherein secondary steps with a step depth of less than 5 μm are formed on the lateral faces of the stack between two immediately successive semiconductor layers.

7. The stacked semiconductor structure according to claim 1, wherein the semiconductor diodes have a partial voltage, and wherein a deviation in partial voltage between the semiconductor diodes is less than 10%.

8. The stacked semiconductor structure according to claim 1, wherein the semiconductor diodes each have the same semiconductor material.

9. The stacked semiconductor structure according to claim 1, wherein the stack has a base area smaller than 4 mm² or smaller than 2 mm².

10. The stacked semiconductor structure according to claim 1, wherein the base area of the stack is quadrilateral or circular in design.

11. The stacked semiconductor structure according to claim 1, wherein a first terminal contact is formed on the top of the stack as a continuous, first metal contact in the vicinity of the edge or as a single contact area on the edge.

12. The stacked semiconductor structure according to claim 1, wherein a second terminal contact is formed on the bottom of the substrate.

13. The stacked semiconductor structure according to claim 1, wherein the stack includes III-V materials or is made of III-V materials.

14. The stacked semiconductor structure according to claim 1, wherein the substrate includes germanium or gallium arsenide.
